(19) United States
(12) Patent Application Publication
(10) Pub. No.: US 2014/0240927 A1
(43) Pub. Date: Aug. 28, 2014

(54) ELECTRONIC MODULE

(71) Applicants: Holger Braun, Stuttgart (DE); Helmut Bubeck, Beilstein (DE); Matthias Lausmann, Murr (DE); Ralf Schinzel, Marbach Am Neckar (DE); Klaus Voigtlaender, Wangen (DE); Thomas Mueller, Leonberg (DE); Benjamin Bertsch, Lichtenstein (DE)

(72) Inventors: Holger Braun, Stuttgart (DE); Helmut Bubeck, Beilstein (DE); Matthias Lausmann, Murr (DE); Ralf Schinzel, Marbach Am Neckar (DE); Klaus Voigtlaender, Wangen (DE); Thomas Mueller, Leonberg (DE); Benjamin Bertsch, Lichtenstein (DE)

(73) Assignee: ROBERT BOSCH GMBH, Stuttgart (DE)

(21) Appl. No.: 14/009,166

(22) PCT Filed: Feb. 29, 2012
(86) PCT No.: PCT/EP12/53420

§ 371 Date: Oct. 1, 2013

(30) Foreign Application Priority Data
Apr. 1, 2011 (DE) 10 2011 006 632.2

(51) Int. Cl. H05K 7/06; H05K 7/20

(52) U.S. Cl. CPC H05K 7/06; H05K 7/20509; H05K 2007/204
USPC 361/707; 361/760

(57) ABSTRACT

The invention relates to an electronic module comprising at least one electronic or electric component (3), a base plate (4), and a support plate (2), in particular a printed circuit board or a substrate. Said support plate (2) is arranged on the base plate (4) and comprises conductor paths. Said base plate (4) comprises a blind hole-type recess (5) on a side oriented towards the support plate (2). The component (3) is in contact on the support plate (2) and is arranged in the recess (5) of the base plate (4).

### TECHNICAL FIELD

The present invention relates to an electronic module and in particular to a transmission control module for motor vehicles.

In the prior art, a plurality of sensors is required at multiple locations, for example, in the case of transmission control systems in order to acquire different signals, as, e.g., temperature, pressure and rotational speed. Feed lines to said sensors consist, for example, of flex foils or cables and are connected to the transmission controller which typically comprises a small printed circuit board. As a result, a very large assembly outlay is incurred and the necessary connections between sensors and printed circuit board are relatively expensive. In addition, a large number of procedural steps, as, e.g., bonding, soldering, welding or adhesive bonding, are required. It would therefore be desirable to provide a cost effective electronic module which particularly can be used in transmission control systems of motor vehicles.

### SUMMARY

The inventive electronic module comprising the features of claim 1 has in contrast the advantage that a cost effective and simply designed module can be produced, which in particular makes a modular design for applications in different motor vehicles possible. In addition, an overall construction height of the module can be reduced in accordance with the invention. This is achieved according to the invention by virtue of the fact that the electronic module comprises a base plate and a support plate, on which support plate an electronic or electric component is arranged. The support plate is thereby arranged on the base plate, and said base plate comprises a blind hole-type recess for receiving at least one electronic or electric component on a side oriented towards the support plate. The component is connected to the support plate, in particular to a printed circuit board or substrate, and is arranged in the recess in the base plate. This facilitates a reduction of the total construction height of the module as well as a side protection of the component arranged in the recess.

The dependent claims exhibit preferred modifications to the invention.

A sensor is furthermore preferably arranged on a side of the support plate facing away from the base plate. The sensor can preferably be a pressure sensor or a temperature sensor or a position sensor or an attitude sensor.

The electronic component arranged in the recess is furthermore preferably an interference suppression assembly. In a particularly preferred manner, the interference suppression assembly is thereby arranged on the support plate at a rear position in relation to a component in which interference is to be suppressed. As a result, it is especially possible for shielding measures by said interference suppression assembly to be provided directly at a source of electromagnetic interferences. Said interference suppression assembly particularly achieves a high suppression of interference as a result of the close proximity thereof to a component in which interference is to be suppressed.

According to a further preferred embodiment of the invention, the electronic component which is arranged in the recess in the base plate is a small modular printed circuit board. Said modular printed circuit board can thereby be arranged in a well protected manner on the support plate.

A sealing compound furthermore preferably completely fills a cavity of the recess of the base plate. In so doing, the sealing compound is preferably made from a material which has very good thermal conductivity properties.

In a particularly preferred manner, the base plate is designed as a cooling plate and in particular as a sheet metal plate or an aluminum plate.

According to a further preferred embodiment of the invention, the support plate comprises a base area and at least one connection element, which is a part of the base area and is positioned at an angle to said base area, a component, in particular a sensor, being arranged in the connection element. Said connection element is thus formed from a part of the support plate and is tilted upwards at the desired angle, preferably 90°, to the base area. In particular, a simple and cost-effective production of the electronic module can thereby be facilitated. This results from the fact that the electronic component can be equipped in the plane of the base area by means of surface technology, the connection element is then exposed from said base area and finally said connection element together with the component is bent at the desired angle out of the plane of said base area. Support plates are basically commercial substrates, in particular multi-layered substrates, for example substrates having at least one copper layer and at least one insulation layer. The connection element is preferably milled from the base area. In so doing, the connection element has, for example, a width of 3-7 mm starting from the intended bending line in the substrate. The connection element is pivoted upward in a radius along the intended bending line. Experiments show that such commercial substrates withstand multiple bending without incurring damage.

A support element is furthermore preferably provided which supports the connection element. The support element can, for example, be fastened to the connection element using clips.

### BRIEF DESCRIPTION OF THE DRAWINGS

A preferred exemplary embodiment of the invention is described below in detail with reference to the accompanying drawings. In the drawings:

FIG. 1 shows a schematic, perspective and partially cutaway view of an electronic module according to an exemplary embodiment of the invention, and

FIG. 2 shows a sectional view of a section of the electronic module from FIG. 1.

### DETAILED DESCRIPTION

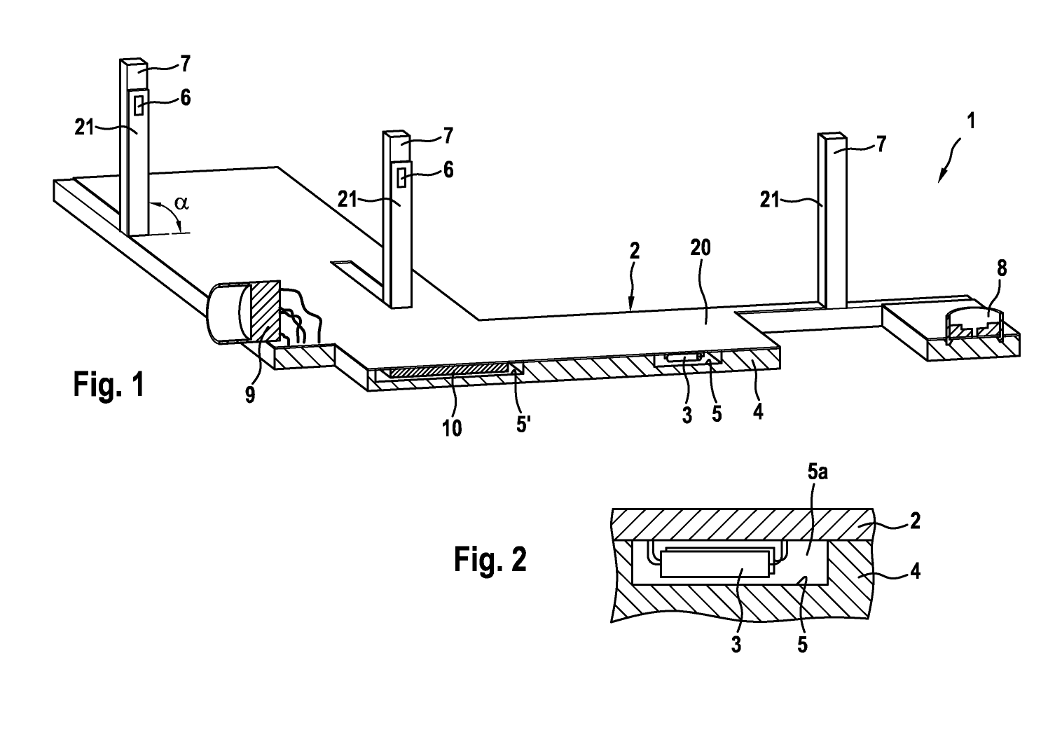

An electronic module 1 according to a preferred exemplary embodiment is described below in detail with reference to the FIGS. 1 and 2. As can be seen in FIG. 1, the electronic module 1 comprises a support plate 2 which can, e.g., be a printed circuit board or a substrate. A variety of components can be arranged on the support plate according to need. The electronic module 1 further comprises a base plate 4, which is an aluminum plate in this exemplary embodiment. The support plate 2 is thereby laminated to one side of the base plate 4.

The base plate 4 further comprises a blind hole-type recess 5 on a side oriented towards the support plate 2. As can especially be seen in FIG. 2, the electronic or electric component 3 is thereby attached to the support plate 2 such that it protrudes into the cavity 5a of the recess 5. The recess 5 is designed having such a depth that the component 3 is completely accommodated. In this exemplary embodiment, the components 3 are designed as interference suppression components. An interference suppression of the other components disposed, for example, above the interference suppression components can thus result directly at an interference source and has a high interference suppression effect because of short connecting paths.

It should further be noted that the cavity 5a of the recess 5 can also be partially or completely filled with a sealing compound or paste or an adhesive.

As can further be seen from FIG. 1, An HDI printed circuit board (HDI: high density interconnect) can, for example, be disposed in a further recess 5. Such HDI printed circuit boards are compactly designed printed circuit boards with high packing density. The HDI printed circuit board 10 can, for example, be disposed in the recess 5 by means of a slug-up configuration so that rapid heat dissipation into the base plate 4 is possible. In order to reliably fix the modular printed circuit board 10, said board can also further be fixed to the bottom and/or side walls of the recess 5 using an adhesive.

As can further be seen from FIG. 1, additional electronic components, such as, for example, a pressure sensor 8, can be disposed at arbitrary positions on the support plate 2. In addition, the reference numeral 9 denotes a plug connector.

As can further be seen from FIG. 1, the support plate 2 comprises a base area as well as a plurality of connection elements 21. The connection elements 21 are bent upwards from the base area at an angle α of 90°. Depending on the length of the connection elements, sensors 6, which are arranged in an end region of each connection element 21, are thereby disposed in the space relative to the base area 20. The reference numeral 7 denotes a separate reinforcing element which is fixed to the base plate 4 and supports the connection elements. The connection elements and the reinforcing elements 7 can, for example, be connected by means of clips. It should be noted that instead of using the reinforcing elements 7, it is in principle also possible for a region of the base plate 4 corresponding to the connection element to be exposed and to be tilted upwards together with said connection element. The connection elements 21 are preferably separated from the base area 20 by means of a milling process. In so doing, a milling process on one side can be sufficient if the connection element is formed on an edge region of the support plate 2 (in FIG. 1 the connection element 21 on the far left); or a milling process is carried out on three sides (in FIG. 1 the central connection element 21). Hence, a modular design can be achieved, whereby the electronic module 1 according to the invention is particularly suitable as a transmission control module, which can be adapted to different variants, for example to different motor vehicles. In so doing, assembly costs and processing costs, such as bonding, soldering, welding or adhesive bonding of electronic components, can particularly be reduced.

1. An electronic module, comprising:
at least one electronic or electric component (3),
a base plate (4) and
a support plate (2), said support plate (2) being arranged on the base plate (4) and comprising conductor paths,
wherein said base plate (4) comprises a blind hole-type recess (5) on a side oriented towards the support plate (2), and
wherein the component (3) is in contact on the support plate (2) and is arranged in the recess (5) of the base plate (4).

2. The electronic module according to claim 1, characterized in that at least one sensor (6, 8) is arranged on a side of the support plate (2) facing away from the base plate (4).

3. The electronic module according to claim 1, characterized in that the component (3) is an interference suppression component.

4. The electronic module according to claim 3, characterized in that the interference suppression component is arranged on the support plate (2) at a rear position in proximity of a component in which interference is to be suppressed.

5. The electronic module according to claim 1, characterized in that the component (3) is a HDI printed circuit board.

6. The electronic module according to claim 1, characterized in that a cavity (5a) of the recess (5) is completely or partially filled with a sealing compound.

7. The electronic module according to claim 1, characterized in that the base plate (4) is embodied as a cooling plate.

8. The electronic module according to claim 1, characterized in that the component (3) arranged in the recess (5) is fixedly bonded in said recess (5) by means of an adhesive.

9. The electronic module according to claim 1, characterized in that the support plate (2) comprises a base area (20) and at least one connection element (21), which is a part of the base area (20) and is positioned at an angle (α) to said base area (20), a component being arranged in the connection element (21).

10. The electronic module according to claim 9, further comprising a reinforcing element (7) which supports the connection element (21).

11. The electronic module according to claim 1, characterized in that the support plate (2) is a printed circuit board or a substrate.

12. The electronic module according to claim 1, characterized in that the base plate (4) is embodied as a cooling plate made from aluminum.

13. The electronic module according to claim 1, characterized in that the support plate (2) comprises a base area (20) and at least one connection element (21), which is a part of the base area (20) and is positioned at an angle (α) to said base area (20), a sensor (6) being arranged in the connection element (21).

14. The electronic module according to claim 1, characterized in that a cavity (5a) of the recess (5) is completely or partially filled with a sealing compound which has a very good thermal conductivity.
